(19) United States
(12) Patent Application Publication
(10) Pub. No.: US 2008/0050889 A1
(43) Pub. Date: Feb. 28, 2008

(54) Hotwall reactor and method for reducing particle formation in GaN MOCVD

(75) Inventors: David Bour, Cupertino, CA (US); Jacob Smith, Santa Clara, CA (US); Sandeep Nijhawan, Los Altos, CA (US); Lori D. Washington, Union City, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/510,107

(22) Filed: Aug. 24, 2006

(51) Int. Cl. H01L 21/20

(52) U.S. Cl. 438/479

(57) ABSTRACT

Systems and methods to suppress the formation of parasitic particles during the deposition of a III-V nitride film with, e.g., metal-organic chemical vapor deposition (MOCVD) are described. In accordance with certain aspects of the invention, a hotwall reactor design and methods associated therewith, with wall temperatures similar to process temperatures, so as to create a substantially isothermal reaction chamber, may generally suppress parasitic particle formation and improve deposition performance.

### BACKGROUND OF THE INVENTION

Group III-V semiconductors are increasingly being used in light-emitting diodes (LEDs) and laser diodes (LDs). Specific III-V semiconductors, such as gallium nitride (GaN), are emerging as important materials for the production of shorter wavelength LEDs and LDs, including blue and ultra-violet emitting optical and optoelectronic devices. Thus, there is increasing interest in the development of fabrication processes to make low-cost, high-quality III-V semiconductor films.

One widely used process for making III-V nitride films like GaN is hydride vapor-phase epitaxy (HVPE). This process includes a high-temperature, vapor-phase reaction between gallium chloride (GaCl) and ammonia (NH₃) at a substrate deposition surface. The GaCl precursor is produced by passing hydrogen chloride (HCl) gas over a heated, liquid gallium supply (melting point 29.8° C.). The ammonia may be supplied from a standard gas source. The precursors are brought together at the heated substrate, where they react and deposit a layer of GaN. The HVPE deposition rate is high (e.g., up to 100 μm/hr) and provides a relatively fast and cost effective method of making GaN films.

However, the HVPE also has drawbacks for forming GaN and other III-V compound films. The HCl gas is not completely consumed when forming the GaCl, and the substrate is exposed to significant amounts of HCl during film deposition. For substrates like silicon that are etch-sensitive towards HCl, a pre-film anti-etch layer needs to be deposited to protect the substrate from being damaged or destroyed. The additional layer needs to be carefully selected so that it minimally interferes with the formation of the GaN film. At the very least, the formation of the anti-etch layer will add additional cost and time to the GaN film deposition process.

In addition, the high deposition rates that characterize HVPE processes make them difficult to use with low levels of dopant materials and for forming complex heterostructures. Dopants are often important to define the electrical and optoelectronic properties of a III-V compound LED, LD, transistor, etc. Doping steps done after the GaN film is deposited may not provide an adequate concentration or homogeneity of the dopant in the film. When post-deposition doping is possible at all, it will at the very least add additional cost and time to the GaN film deposition process.

Another major drawback of HVPE is the difficulty of using the process to grow alloys of III-V nitrides, such as aluminum gallium nitride (AlGaN) and indium gallium nitride (InGaN). These and other nitride alloys offer a much larger variety of heterostructures than single-metal nitrides, and are already suggesting many new optoelectronic device applications. But unfortunately generating stable gas precursors for aluminum (e.g., aluminum chloride) and indium (e.g., indium chloride) has proven more difficult than the generation of GaCl.

For example, aluminum has a much higher melting point (about 660° C.) than gallium, and the chloride salt of aluminum (AlCl₃) quickly solidifies into a low vapor pressure solid even under high-temperature HVPE reactor conditions. When HCl passes over aluminum metal, most of the AlCl₃ precipitates out of the gas flow, and only a small fraction reaches the deposition substrate to react with a nitrogen precursor and form AlN.

To overcome these and other shortcomings of HVPE III-V compound film formation, another process called metal-organic chemical vapor deposition (MOCVD) is used to form III-V nitride films. MOCVD uses a reasonably volatile metallorganic Group III precursor such as trimethylgallium (TMGa) or trimethylaluminum (TMAl) to deliver the Group III metal to the substrate where it reacts with the nitrogen precursor (e.g., ammonia) to form the III-V nitride film.

MOCVD nitride films are typically deposited at lower temperature than HVPE films, allowing the fabrication process to have a lower thermal budget. It is also easier to combine two or more different Group III metallorganic precursors (e.g., Ga, Al, In, etc.) and make alloy films of GaN (e.g., AlGaN, InGaN, etc.). Dopants may also be more easily combined with the precursors to deposit an in-situ doped film layer.

MOCVD film depositions, however, also have drawbacks. These include slower deposition rates for MOCVD than HVPE. MOCVD typically deposits a film at about 5 μm/hr or less compared with 50 μm/hr for HVPE. The slower deposition times make MOCVD a lower throughput and more expensive deposition process than HVPE.

Several approaches have been tried to increase the throughput of GaN depositions with MOCVD: In one approach, batch reactors have been tried that are capable of simultaneously growing films on many wafers or over large areas. In a second approach, attempts were made to increase the rate of GaN film growth and heterostructures. Both approaches have had difficulties.

Scale up to large areas has proved difficult because the GaN must be grown at relatively high pressures (e.g., several hundred Torr), and at these pressures the flow velocity in a large reactor is low, unless the total flow through the reaction is made extraordinarily high. Consequently, the precursor stream becomes depleted of reactants over a short distance, making it difficult to grow a uniform film over a large area.

Attempts to increase the deposition rates of a GaN film by increasing the concentration (i.e., partial pressures) of the organo-gallium and ammonia precursors have also proved difficult. FIG. 1A shows a graph of a growth rate for a GaN film as a function of the total pressure in the MOCVD reactor. These graphs are based on simulations by STR of GaN film growth in a Thomas Swan reactor with a close-coupled showerhead injector. The graph shows a steep drop in the rate as the pressure in the reactor increases above about 300 torr.

The decrease in GaN film growth rate with increasing MOCVD reactor pressure is attributed to the formation of gas-phase parasitic particles that consume the Ga and N precursors that would otherwise be used to grow the film. These parasitic particles form in a thin thermal boundary layer over the wafer substrate, where local gas temperatures become sufficiently high to promote a pyrolytic reaction between the Group III precursors and ammonia (the nitrogen precursor). Once formed, the hot, suspended (by thermophoresis) particles become nuclei for additional deposition, thereby growing and further depleting reactants from the gas stream, until they are flushed out of the chamber. Thus, there is competition between the desired film growth and the parasitic particle growth. Parasitic particle formation increases when the partial pressures of the Group III and/or Group V precursors increase, or when the thermal boundary layer around the wafer substrate is expanded.

In the case of GaN films grown with a trimethylgallium precursor, the film growth rate eventually saturates with respect to the trimethylgallium flow, making it difficult to realize growth rates greater than about 5 μm/hr. The formation of the parasitic particles can also degrade the optoelectronic qualities of the deposited GaN film.

Because the parasitic particle formation depends on the partial pressures of the Group III and V precursors, it may be possible to increase the growth rate of the MOCVD deposited film by diluting the precursor gas stream with more carrier gas (e.g., hydrogen (H₂), helium, etc.). However, attempts to dilute the precursor gas stream hurt the quality of the III-V film that was deposited. Maintaining high partial pressures of the precursors, especially a high ammonia partial pressure in the case of nitride film depositions, appears to be beneficial in the growth of high quality films.

Parasitic particle formation in MOCVD film depositions can be even more severe for alloys of gallium nitride. FIG. 1B, for example, shows a graph of a STR simulation of the deposition rate of AlGaN as a function of the pressure in an Aixtron planetary reactor. The graph shows an even steeper drop off in the film formation rate versus reactor pressure during the formation of a AlGaN film than for an unalloyed GaN film. Similar decreases in film growth rates were shown in simulations for Thomas Swan and Veeco reactor geometries.

AlGaN films are used in LED heterostructures where a p-type layer is grown over a InGaN well active region. It is therefore beneficial to grow the AlGaN film with a reasonably high hole concentration, and free of nonradiative or compensating defects. Unfortunately, high total pressures and high ammonia flows are best for growing AlGaN films with these qualities, but growing these films with the requisite Al content by MOCVD is extremely challenging due to the formation of the parasitic particles.

In another example, InGaN film growth is also limited by parasitic particle formation. FIG. 1C shows a graph of an InGaN film growth rate as a function of reaction pressure. The graph was derived from growth simulation done with a Thomas Swan showerhead reactor geometry at various pressures. While the formation of parasitic particles in MOCVD depositions of InGaN is not as pronounced as for AlGaN, it is still significant enough to limit the growth rate of the films. InGaN films have applications in the quantum well active regions of laser diodes and LEDs. Without the formation of the parasitic particles, growth of InGaN films could be performed at higher pressures and higher ammonia flow, both of which would be beneficial for the optoelectronic quality (e.g., high internal efficiency) and p-type doping in LDs and LEDs. Thus, there is a need for systems and methods that control parasitic particle formation while increasing the throughput of MOCVD formed III-V nitride films.

### BRIEF SUMMARY OF THE INVENTION

To address such needs and others, in certain aspects of the invention, a method of suppressing parasitic particle formation in a metal organic chemical vapor deposition process for deposition of III-V nitride films is provided. The method generally comprises: providing a substrate to a reaction chamber including at least a susceptor for supporting the substrate and a top-plate disposed above the substrate; introducing a Group-III organometallic precursor and at least nitrogen-containing precursor to the reaction chamber, wherein the nitrogen-containing precursor reacts with the Group-III organometallic precursor; and forming a deposition layer on the substrate from a reaction mixture comprising the Group-III organometallic precursor and the nitrogen-containing precursor under substantially isothermal reaction conditions such that parasitic particle formation is suppressed in the reaction chamber.

In certain embodiments, the reaction chamber top-plate is heated to a temperature substantially isothermal with the susceptor to thereby provide the substantially isothermal reaction conditions. Without being limited, the deposition layer may be selected from a nucleation layer or an epitaxial layer.

In other aspects of the invention, a method of suppressing parasitic particle formation during formation of a gallium nitride layer on a sapphire substrate is provided. Such methods generally comprise: introducing ammonia to a reaction chamber that includes the sapphire substrate; introducing an organo-gallium compound to a reaction chamber under substantially isothermal reaction conditions such that parasitic particle formation is suppressed in the reaction chamber; and forming a gallium nitride layer on the sapphire substrate.

In certain embodiments, the reaction chamber includes at least a susceptor for supporting the sapphire substrate and a top-plate disposed above the sapphire substrate; and wherein the reaction chamber top-plate is heated to a temperature substantially isothermal with the susceptor to thereby provide said substantially isothermal reaction conditions.

These and other aspects of the invention will be described in more detail throughout the present specification and more particularly below in conjunction with the following drawings.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIGS. 1A-C are graphs plotting the deposition rates of III-V nitride films as a function of pressure in a reaction chamber;

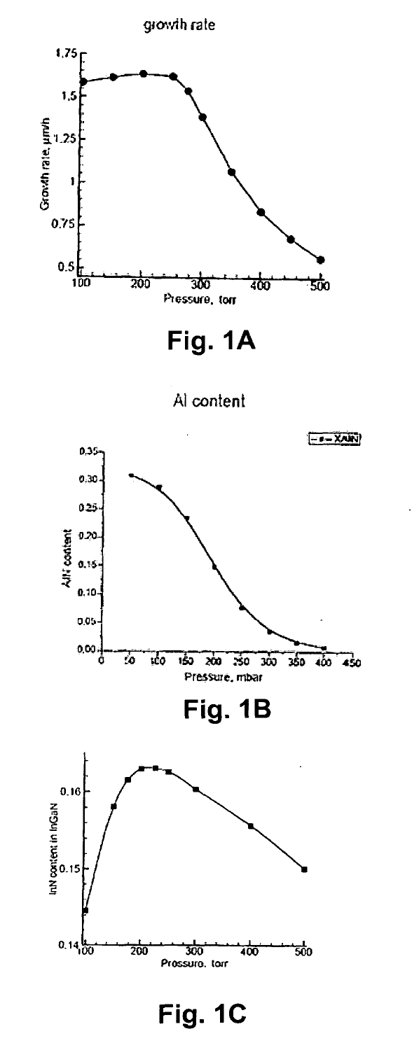

FIG. 2 provides a schematic illustration of a structure of a GaN-based LED;

FIG. 3 is a flowchart illustrating steps in processes of forming a deposition layer on a substrate according to embodiments of the invention;

FIGS. 4A and 4B are flowcharts illustrating steps in combined MOCVD/HVPE processes of forming III-V layers according to embodiments of the invention;

FIG. 5 is a simplified representation of an exemplary CVD apparatus that may be used in implementing certain embodiments of the invention;

FIG. 6 provides a schematic illustration of a multichamber cluster tool used in embodiments of the invention;

FIG. 7A-7C illustrate simulated comparisons of particulate distributions for varied temperatures of nearby hotwall;

FIG. 8 illustrates simulated results of deposition rate for varied temperatures of nearby hotwall;

FIG. 9A-9F illustrated simulated results of comparative cold-wall versus hotwall reactors.

### DETAILED DESCRIPTION OF THE INVENTION

Systems and methods to suppress the formation of parasitic particles during the deposition of a III-V nitride film with, e.g., metal-organic chemical vapor deposition (MOCVD) are described. In accordance with certain aspects of the invention, a hotwall reactor design and methods associated therewith, with wall temperatures similar to process temperatures, so as to create a substantially isothermal reaction chamber, may generally suppress parasitic particle formation and improve deposition performance.

Without intending to be limited by theory, as process gases are introduced to a reaction chamber and heat up, GaN is formed in the gas phase and GaN particles nucleate (J. Phys. Chem. A 2005, 109, 133-137). Thermophoresis in a cold-wall reactor will cause heated gases to convect away from the substrate surface and into the bulk gas flow, allowing for particle nucleation and growth. However, in accordance with certain aspects of the invention, in a hotwall reactor, the process gases experience less thermophoresis and therefore are more likely to remain near the substrate surface and deposit on the wafer (rather than form particles). Additionally, hotwall reactor methodologies in accordance with the invention will heat the bulk gas, causing expansion, reducing residence time of the reaction gases, and reducing the reaction time available for the reaction gases to form particles. Further, without intending to be limited by theory, the Ga precursor compounds will tend to deposit on the hot wall of the reactor, rather than forming particles in the gas phase. This deposition of Ga deposition is then easily burned off during cleaning operations, as opposed to difficult removal operations of GaN particles.

Additionally, the hotwall reactor methodologies in accordance with aspects of the invention more closely approximate an isothermal reaction environment, as compared to conventional cold-wall reactors, which are inherently non-isothermal. Such isothermal reaction conditions result in improved consistency of film quality, composition, and uniformity across the substrate. In addition, temperature gradient particle formation is minimized within the reaction chamber, as are temperature gradient reactant depletion inefficiencies. Generally, in conventional non-isothermal systems, reactant gases are heated in hot regions and then convect to a relatively cooler regions. Without intending to be limited by theory, this causes a nucleation of particles because (1) in the hot region, gas phase reactions favor formation of GaN or similar MOCVD/HVPE gas-phase specie; and (2) in the cold region, the partial pressure of this specie formed in the hot region can exceed its vapor pressure in the cold region and thus will precipitate out of the gas phase (i.e., form particles). Contrary to this, the isothermal environment of the present invention avoids these inefficiencies, and will not form particles in this manner.

The hotwall reactor methodologies, in accordance with certain aspects of the invention, may thereby reduce or eliminate parasitic particle formation and subsequent depletion of reactant precursors to improve efficiency of, e.g., III-V nitride film growth.

By way of example, the particle suppression methods and systems of the invention, e.g., allow the Group III and Group V precursors to be supplied to the reaction chamber at higher partial pressures than would otherwise be possible for growing high quality III-V films with MOCVD. The ability to increase the partial pressures of the film forming precursors without also forming more parasitic particles allows the III-V films to be grown at faster deposition rates (e.g., rates of about 5 μm/hr or more), and with higher optoelectronic quality (e.g., higher internal efficiency, superior p-type doping, etc.) than films grown at lower reactor pressures.

### I. Exemplary III-V Film Structures

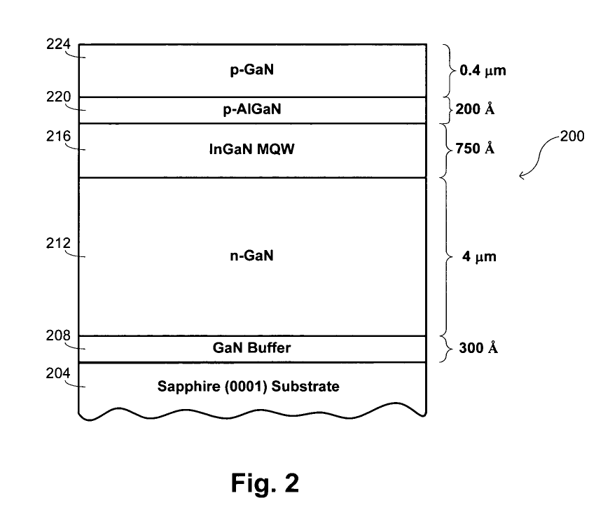

Embodiments of the systems and methods described may be used to form III-V devices that act as light emitting diodes and/or laser diodes, among other devices. FIG. 2 shows an example of a III-V device that may be made using the present systems and methods. A GaN-based LED structure 200 is shown formed over a sapphire (0001) substrate 204. An n-type GaN layer 212 is deposited over a GaN buffer layer 208 formed over the substrate. An active region of the device is embodied in a multi-quantum-well layer 216, shown in the drawing to comprise an InGaN layer. A pn junction is formed with an overlying p-type AlGaN layer 220, with a p-type GaN layer 224 acting as a contact layer.

Other III-V devices may also be made by the present invention, including laser diodes (LDs), high-electron mobility transistors, and other opto-electronic devices.

### II. Exemplary Fabrication Methods

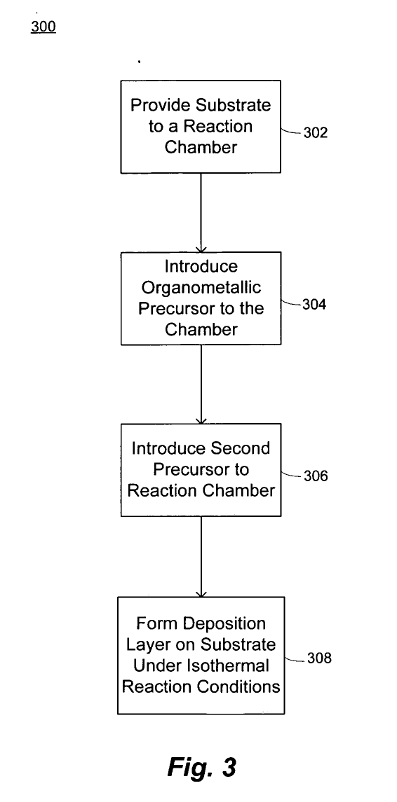

FIG. 3 shows a flowchart illustrating steps in processes 300 of forming a deposition layer on a substrate according to embodiments of the invention. The process 300 includes providing a substrate upon which the deposition layer will be formed to a reaction chamber 302. The reaction chamber may generally include a susceptor which supports the substrate and a top-plate disposed above the susceptor and substrate to define, at least in part, a hotwall reaction surface. The hotwall reaction surface generally encloses an isothermal reaction zone above the substrate surface to minimize formation of parasitic particles during deposition processing.

The deposition layer may be, e.g., a nucleation layer, a epitaxial layer, etc., and may include a single Group III metal or an alloy, depending on the end use of the device being constructed, and the specific step of the deposition process. Deposition temperatures and pressures may vary, depending on the specific layer and starting materials of interest, as recognized by those skilled in the art. In certain embodiments, the substrate may be any substrate that a group III-V nucleation layer can be formed by, e.g., MOCVD. However, the invention is not so limited, e.g., hydride vapor phase epitaxy (HVPE) may alternatively be used in other embodiments. These may include, for example, substrate wafers made from sapphire (Al₂O₃), substantially pure silicon (Si), silicon carbide (SiC), spinel, zirconium oxide, as well as compound semiconductor substrates such as gallium-arsenide (GaAs), lithium gallate, indium phosphide (InP), and single-crystal GaN among other substrates.

With the substrate in the reaction chamber, the film forming precursors may be introduced to start the deposition of the deposition layer. In the flowchart shown in FIG. 3, embodiments of the process may include introducing an organometallic precursor to the reaction chamber 304. The organometallic precursor may include a Group III metal and a carbon group, among other constituents. For example, the precursor may include an alkyl Group III metal compound such as an alkyl aluminum compound, an alkyl gallium compound, and/or an alkyl indium compound, among others. Specific precursor examples may include trimethylaluminum (TMA), triethyl-aluminum (TEA), trimethylindium (TMI), triethylindium (TEI), trimethylgallium (TMG), and triethylgallium (TEG). Larger sized alkyl groups, such as propyl, pentyl, hexal, etc., may also be combined with the Group III metal. Different sized alkyl groups may also be combined in the same precursor, such as ethyldimethylgallium, methyldiethyl-aluminum, etc. Other organic moieties such as aromatic groups, alkene groups, alkyne groups, etc. may also be part of the organometallic precursor.

Two or more organometallic precursors may be introduced to the reaction chamber to react and form a layer that includes a metallic alloy. For example, the organometallic precursors may include two or more Group III metals (e.g., Al, Ga, In) that form a nitride of a Group III alloy on the substrate, such as AlGaN, InGaN, InAlN, InAlGaN, etc. In AlGaN, for example, TMG and TMA may be introduced together into the reaction chamber with a nitrogen precursor (e.g., ammonia) to form the alloyed III-V layer.

The organometallic precursor may also be a halogenated precursor, with the halogen group attached to either the metal atom, the organic moiety, or both. Examples include diethylgallium chloride, chloromethlydiethylgallium, chlorodiethylgallium chloride, etc.

A second precursor may be introduced to the reaction chamber 306 that reacts with the organometallic precursor in an isothermal reaction zone around the deposition surface of the substrate. When the deposition layer is a metal-nitride layer, the second precursor may be a nitrogen containing precursor, such as ammonia (NH₃). The second precursor may flow in a separate gas stream into the reaction chamber that intersects with the organometallic precursor gas stream in a space in the heated reaction zone above the substrate.

Carrier gases such as helium, hydrogen, argon, or nitrogen may be used to facilitate the flow of the precursors and particle suppression compounds in the reaction chamber, as well as adjust the total pressure in the chamber. The carrier gas may be premixed with the precursor gas before entering the chamber, and/or may enter the chamber in an unmixed state through a separate flow line.

When the precursors react in the isothermal reaction zone, least a portion of the reaction products forms the deposition layer on the substrate 308 under substantially isothermal reaction conditions. In certain embodiments, substantially isothermal reaction conditions include reaction conditions wherein the temperature gradient in the reaction zone (e.g., the zone wherein the deposition layer precursors react to form the deposition layer—such as the zone between the susceptor and the reactor top-plate directly over the substrate wafer surface) do not vary by more than about 100° C., about 50° C., about 25° C., etc., once temperature equilibration is reached. In certain embodiments, the entering process gases may be preheated to aid in maintaining the isothermal reaction zone.

The deposition layer deposition rate and film properties may be controlled, at least in part, by adjustable parameters of the reaction chamber, including the chamber temperature, pressure, and fluid flow rate, and partial pressures of the precursors, carrier gases and particle suppression compound(s). Further, in accordance with the present invention, the deposition rates may additionally be controlled based, in part, on the creation on the isothermal reaction zone above the substrate. For instance, reactant concentrations may be optimized through maintenance of a substantially isothermal reaction zone surrounding the deposition surface of the substrate, thereby aiding in control of deposition rates and efficiencies.

For example, in accordance with certain embodiments of the invention, the reaction products form the deposition layer on the substrate in step 308 under substantially isothermal reaction conditions. the temperature of the reaction zone around the substrate wafer may be adjusted from about 23° C. to about 1100° C. by an external heat source surrounding the reaction zone, or the susceptor surface may integrate heating elements. The heat source heats the walls of the reactor (i.e., a hot-walled reaction chamber), which in turn heats the substrate. Under hot-walled reactor conditions, the precursors are heated as they enter the reaction chamber, and can react around the heated chamber walls (e.g., the top-plate) as well as the substrate.

As described above, in accordance with certain aspects of the invention, the substantially isothermal reaction conditions within the reaction zone allow for less thermophoresis within the reaction zone. Thus, the reactants are more likely to remain near the substrate surface and deposit on the wafer (rather than form particles). Additionally, hotwall reactor methodologies in accordance with the invention will heat the bulk gas, causing expansion, reducing residence time of the reaction gases, and reducing the reaction time available for the reaction gases to form particles. Further, without intending to be limited by theory, the Ga precursor compounds will tend to deposit on the hot wall of the reactor, rather than forming particles in the gas phase. This deposition of Ga deposition is then easily burned off during cleaning operations, as opposed to difficult removal operations of GaN particles.

Additionally, the hotwall reactor methodologies in accordance with aspects of the invention more closely approximate an isothermal reaction environment, as compared to conventional cold-wall reactors, which are inherently non-isothermal. Such isothermal reaction conditions result in improved consistency of film quality, composition, and uniformity across the substrate. In addition, temperature gradient particle formation is minimized within the reaction chamber, as are temperature gradient reactant depletion inefficiencies.

Generally, the deposition rate and film quality of the deposition layer may also be determined, in part, by the temperature of the substrate within the substantially isothermal reaction zone. The temperature of the substrate during deposition may be, for example, up to about 200° C., 300° C., 400° C., 500° C., 600° C., 700° C., 800° C., 900° C., 1000° C., 1050° C., or more. The temperature of the substrate may also be adjusted, in part, by controlling the temperature of the streams of precursor gases entering the reaction chamber and surrounding the substrate in the substantially isothermal reaction zone. For example the precursor gases introduced to the reaction chamber may have a temperature ranging from about 15° C. to about 300° C., 400° C., 500° C., 600° C., or 700° C. or more (e.g., so as to aid in maintaining an isothermal reaction zone).

The reactor pressure may also be set during the deposition of the deposition layer. The processing conditions used for deposition of the deposition layer may vary depending on specific applications. The following table provides exemplary processing conditions and precursor flow rates that are generally suitable in the growth of III-V deposition layers:

| Parameter | Value |
|---|---|
| Temperature (° C.) | 500–1500 |
| Pressure (torr) | 50–1000 |
| TMG flow (sccm) | 0–50 |
| TMA flow (sccm) | 0–50 |
| TMI flow (sccm) | 0–50 |
| PH₃ flow (sccm) | 0–1000 |
| AsH₃ flow (sccm) | 0–1000 |
| NH₃ flow (sccm) | 10–100,000 |
| HCl flow (sccm) | 0–500 |
| N₂ flow (sccm) | 0–100,000 |
| Ar flow (sccm) | 0–10000 |
| H₂ flow (sccm) | 0–100,000 |

As will be evident from the preceding description, a process might not use flows of all the precursors in any given process. For example, growth of GaN might use flows of TMG, NH₃, and N₂ in one embodiment; growth of AlGaN might use flows of TMG, TMA, NH₃, and H₂ in another embodiment, with the relative flow rates of TMA and TMG selected to provide a desired relative Al:Ga stoichiometry of the deposited layer; and growth of InGaN might use flows of TMG, TMI, NH₃, N₂, and H₂ in still another embodiment, with relative flow rates of TMI and TMG selected to provide a desired relative In:Ga stoichiometry of the deposited layer.

The isothermal reaction zone conditions may be set to form the deposition layer with a deposition rate of, for example, about 4 μm/hr or more, about 5 ml/hr or more, about 10 μm/hr or more, about 25 μm/hr or more, or about 50 μm/hr or more. Such deposition rates are improved, as compared to those deposition rates from models wherein hotwall reactor methodologies are not used to minimize particle formation, as discussed in further detail in the examples herein. The deposition time may be, for example, about 1, 5, 10, 15, 20, 30, 45, or 60 minutes or more. Deposition layer thicknesses may vary, depending on the type of layer, as recognized by those skilled in the art, e.g., a nucleation layer having a thickness of about 100 Å to about 1000 Å while epitaxial layers may be, e.g., 5 μm or more.

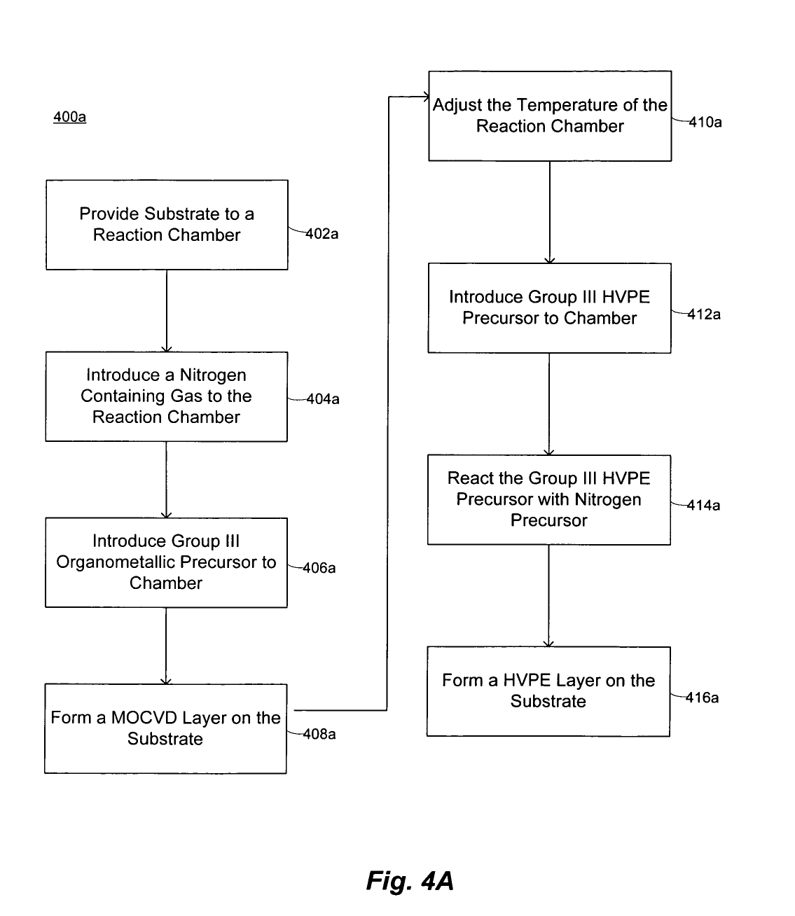

In certain aspects of the invention, the hotwall reactor methodologies of the invention may be used in multi-step deposition processes, wherein III-V nitride-based films having multiple film layers are deposited. In an exemplary embodiment of the invention, FIG. 4A is a flowchart illustrating steps in a combined MOCVD and HVPE process 400a of forming III-V layers according to embodiments of the invention. In this process, MOCVD is used to form a first MOCVD layer (e.g., a III-V nucleation layer) on a substrate, and HVPE is used to form a second HVPE layer (e.g., a bulk III-V layer). The process 400a may include providing a substrate to a reaction chamber 402a. A Group V precursor, i.e., a nitrogen precursor is introduced into the reaction chamber 404 a, followed by a Group III organometallic precursor 406a. The nitrogen precursor (e.g., ammonia) may be introduced with about the same or higher flow rate and/or partial pressure as the Group III organometallic precursor.

The Group III organometallic precursor and the nitrogen precursor may react and form the MOCVD layer under substantially isothermal reaction conditions on the substrate 408a. The MOCVD layer may be formed at a rate of up to 4 μm/hr or more, and may have a thickness of about 10 Å to about 1 μm.

Following the deposition of the MOCVD layer, the temperature of the reaction chamber may be adjusted 410a for the deposition of a HVPE layer. Typically, the temperature is increased for the deposition of the HVPE layer. For example, HVPE deposition temperatures for forming a III-V nitride layer are about 550° C. to about 1100° C. (e.g., about 800° C. to about 1000° C.). This may be higher than the temperatures typically used to form a III-V nitride layer by MOCVD (e.g., about 100° C. to about 700° C., commonly about 300° C. to about 700° C.).

The Group III HVPE precursor may then be introduced to the reaction chamber 412a. The Group III HVPE precursor may be formed by passing a halogen gas (e.g., HCl) over a heated Group III metal (e.g., liquid gallium, aluminum and/or indium). The halogen gas an metal vapor react to form a metal halide (e.g., GaCl) that is introduced into the reaction chamber by a carrier gas (e.g., helium, hydrogen).

The Group III HVPE precursor may react with a nitrogen precursor 414a in the reaction chamber. At least a portion of the reaction products are deposited onto the substrate to form a HVPE layer 416a on the MOCVD layer. The HVPE layer may be formed at a faster deposition rate (e.g., up to about 50 μm/hr) than the MOCVD layer. The HVPE layer may also be thicker than the MOCVD layer (e.g., 2, 3, 4, 5, 6, 10, 20, or more times the thickness of the MOCVD layer).

The process 400a described in FIG. 4a, may be carried out in a single reaction chamber capable of performing both MOCVD and HVPE, or separate reaction chambers dedicated to a single deposition technique. The system used to perform the process 400a may also include reaction chambers of etching, lithography, and annealing, among other additional process steps.

In FIG. 4a, the process 400a used MOCVD to from a first layer on the substrate and HVPE to form a second layer on the first layer. FIG. 4b shows embodiments of a process 400b that reverses the HVPE and MOCVD deposition sequence by forming the HVPE layer before the MOCVD layer. The process 400b may start the same by providing a substrate to a reaction chamber 402b. However, a Group V HVPE precursor, i.e., a nitrogen containing gas, is introduced to the reaction chamber 404b, along with a Group III HVPE precursor 406b. The Group III HVPE precursor and nitrogen containing gas react 408b to form a first HVPE layer on the substrate 410b.

When the process 400b is performed in a single reaction chamber, the process conditions in the chamber may be reconfigured for the second, MOCVD deposition. This reconfiguration may include stopping the flow of the Group III HVPE precursor, and adjusting the temperature of the reaction chamber 412b for the MOCVD deposition. Typically, this means decreasing the temperature of the reaction chamber. A Group III organometallic precursor may then be introduced into the reaction chamber 414b along with the nitrogen containing gas to form the MOCVD layer on the HVPE layer and the substrate 416b. The nitrogen containing gas may flow continuously during the deposition of the HVPE and MOCVD layer, or may be stopped between the depositions.

### Exemplary Substrate Processing System

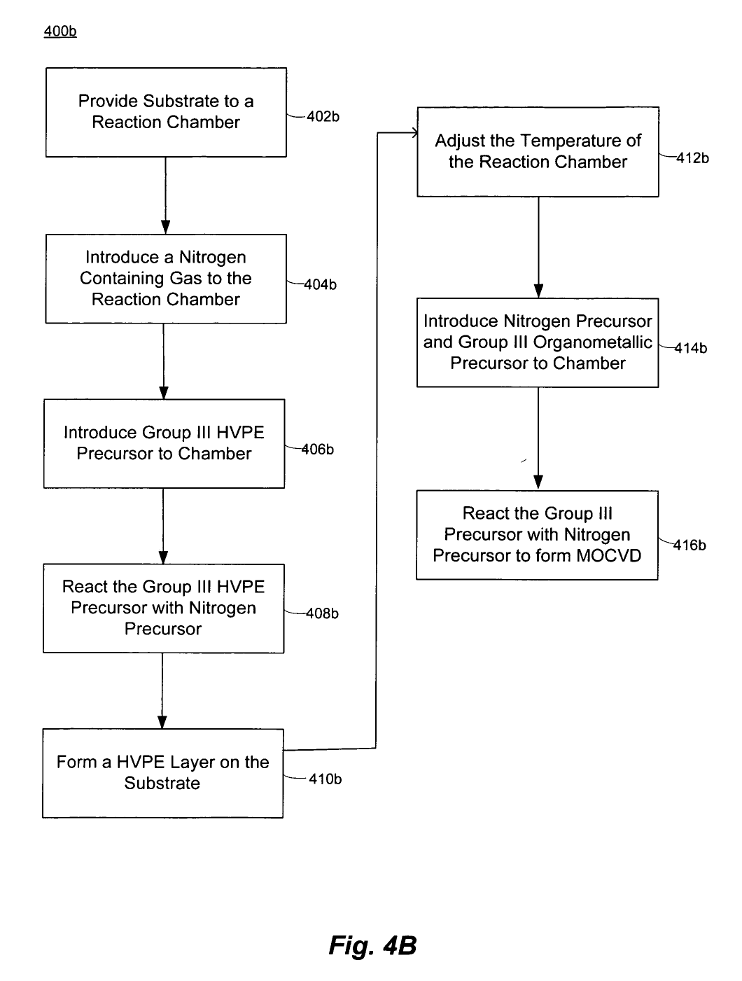

FIG. 5 is a simplified diagram of an exemplary chemical vapor deposition (“CVD”) system, illustrating the basic structure of a chamber in which individual deposition steps can be performed. This system is suitable for performing thermal, sub-atmospheric CVD (“SACVD”) processes, as well as other processes, such as reflow, drive-in, cleaning, etching, deposition, and gettering processes. In some instances multiple-step processes can still be performed within an individual chamber before removal for transfer to another chamber. The major components of the system include, among others, a vacuum chamber 515 that receives process and other gases from a gas or vapor delivery system 520, a vacuum system 525, and a control system (not shown). These and other components are described in more detail below. While the drawing shows the structure of only a single chamber for purposes of illustration, it will be appreciated that multiple chambers with similar structures may be provided as part of a cluster tool, each tailored to perform different aspects of certain overall fabrication processes.

The CVD apparatus includes an enclosure assembly 537 that forms vacuum chamber 515 with a substantially isothermal reaction zone 516. A gas distribution structure 521 disperses reactive gases and other gases, such as purge gases, toward one or more substrates 509 held in position between a substrate support structure 508, generally configured as a susceptor, and top-plate 510. Between top-plate 510 and the substrate 509 in substantially isothermal reaction zone 516. Heaters 526 can be controllably moved between different positions to accommodate different deposition processes as well as for an etch or cleaning process. A center board (not shown) includes sensors for providing information on the position of the substrate.

Different structures may be used for heaters 226. For instance, some embodiments of the invention advantageously use a pair of plates in close proximity and disposed on opposite sides of the substrate support structure 508 to provide separate heating sources for the opposite sides of one or more substrates 509. Merely by way of example, the plates may comprise graphite or SiC in certain specific embodiments. In another instance, the heaters 526 include an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heaters 526 exposed to vacuum chamber 515 are made of a ceramic material, such as aluminum oxide (Al₂O₃ or alumina) or aluminum nitride. In another embodiment, the heaters 526 comprises lamp heaters. Alternatively, a bare metal filament heating element, constructed of a refractory metal such as tungsten, rhenium, iridium, thorium, or their alloys, may be used to heat the substrate. Such lamp heater arrangements are able to achieve temperatures greater than 1200° C., which may be useful for certain specific applications.

In certain aspects of the invention, one or more heaters 526 may optionally be incorporated into substrate support structure 508 and/or top-plate 510, so as to partially aid in controlling the temperature gradient in the substantially isothermal reaction zone 516. Alternatively, the configuration and/or placement of the one or more heaters 526 in the enclosure assembly 537 may partially aid in control of temperature gradients.

Reactive and carrier gases are supplied from the gas or vapor delivery system 520 through supply lines to the gas distribution structure 521. In some instances, the supply lines may deliver gases into a gas mixing box to mix the gases before delivery to the gas distribution structure. In other instances, the supply lines may deliver gases to the gas distribution structure separately, such as in certain showerhead configurations described below. As shown, the gas or vapor delivery system 220 directly enters the substantially isothermal reaction zone 516 through the top. Alternatively, the delivery system may distribute gases into the reaction zone through the side (not shown), so that the reaction gases flow from the side over the surface of the substrate wafer 509.

The gas or vapor delivery system 520 includes a variety of sources and appropriate supply lines to deliver a selected amount of each source to chamber 515 as would be understood by a person of skill in the art. Generally, supply lines for each of the sources include shut-off valves that can be used to automatically or manually shut-off the flow of the gas into its associated line, and mass flow controllers or other types of controllers that measure the flow of gas or liquid through the supply lines. Depending on the process run by the system, some of the sources may actually be liquid or solid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. Alternatively, liquid precursor may be introduced into the gas phase by flowing gases over a liquid source that will react at the liquid-gas interface, for instance, HCl (g)+Ga (l)→GaCl (g)+0.5H₂ (g). During deposition processing, gas supplied to the gas distribution structure 521 is vented toward the substrate surface (as indicated by arrows 523), where it may be uniformly distributed radially across the substrate surface in a laminar flow.

Purging gas may be delivered into the vacuum chamber 515 from gas distribution structure 521 and/or from inlet ports or tubes (not shown) through the bottom wall of enclosure assembly 537. Purge gas introduced from the bottom of chamber 515 flows upward from the inlet port past the heater 526 and to an annular pumping channel 540. Vacuum system 525 which includes a vacuum pump (not shown), exhausts the gas (as indicated by arrows 524) through an exhaust line 560. The rate at which exhaust gases and entrained particles are drawn from the annular pumping channel 540 through the exhaust line 560 is controlled by a throttle valve system 563.

The temperature of the walls of deposition chamber 515 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during other processes, or to limit formation of deposition products on the walls of the chamber. Gas distribution manifold 521 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The system controller controls activities and operating parameters of the deposition system. The system controller may include a computer processor and a computer-readable memory coupled to the processor. The processor executes system control software, such as a computer program stored in memory. The processor operates according to system control software (program), which includes computer instructions that dictate the timing, mixture of gases, chamber pressure, chamber temperature, microwave power levels, pedestal position, and other parameters of a particular process. Control of these and other parameters is effected over control lines that communicatively couple the system controller to the heater, throttle valve, and the various valves and mass flow controllers associated with gas delivery system 520.

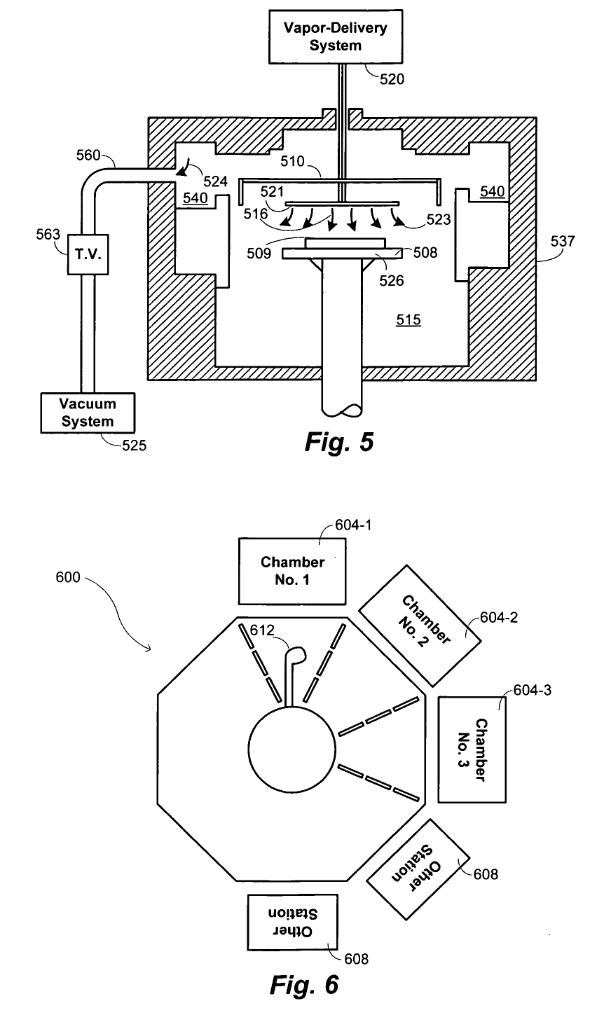

The physical structure of the cluster tool is illustrated schematically in FIG. 6. In this illustration, the cluster tool 600 includes three processing chambers 604 and two additional stations 608, with robotics 612 adapted to effect transfers of substrates between the chambers 604 and stations 608. The structure permits the transfers to be effected in a defined ambient environment, including under vacuum, in the presence of a selected gas, under defined temperature conditions, and the like. Optical access is provided to a transfer chamber in which the transfers are effected through a window 610. A particular advantage of having optical access provided through the transfer chamber, as opposed to through one of the processing chambers 604, is that the window 610 may be made relatively large. A concern with providing optical access to processing chambers is the disturbance that a window or similar structure will have on processing characteristics taking place within the chamber. Since no processing takes place directly on the substrate in the transfer chamber, such concerns are avoided. A variety of optical elements may be included within or outside the transfer chamber to direct the light as desired.

Although the invention is described herein as being implemented in software and executed upon a general purpose computer, those of skill in the art will realize that the invention could be implemented using hardware such as an application specific integrated circuit (ASIC) or other hardware circuitry. As such, it should be understood that the invention can be implemented, in whole or in part, is software, hardware or both. Those skilled in the art will also realize that it would be a matter of routine skill to select an appropriate computer system to controls the systems described herein.

### EXAMPLES

The following examples are provided to illustrate how the general faceplate and systems described in connection with the present invention may be used rapid temperature equilibration. However, the invention is not limited by the described examples.

### A. Example 1

### Reduction in Particle Formation

Simulations were run by STR of GaN film growth in a Thomas Swan reactor with a close-coupled showerhead injector within a hotwall reactor. Pressure was set to 200 Torr; reaction zone temperature was set to 1050° C.; inlet conditions were set to: NH₃ 15 slm, H₂ 20 slm, TMG 135 sccm; and bottom purge inlet was set to H₂ 3 slm. Results of the simulation showed approximately 13% Ga was in particle form at the outlet of the reaction, while approximately 2.6% of the Ga was in particle form at the back edge of the first wafer.

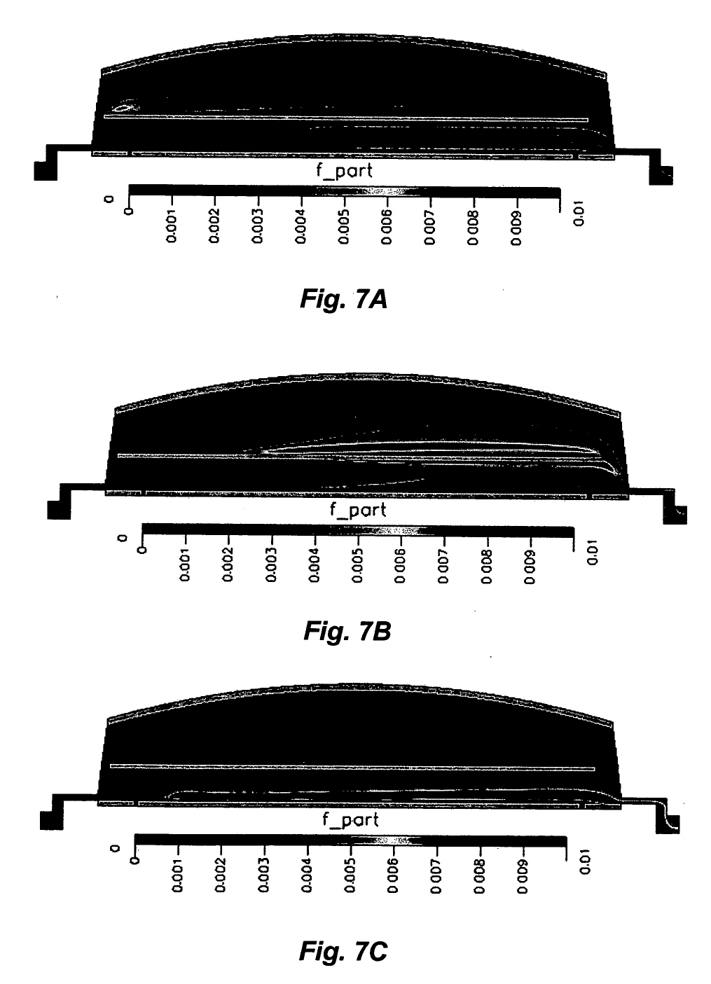

Additional simulations were run comparing varying plate temperatures, to demonstrate the effect on particulate distribution along the plate. Pressure was set to 200 Torr; reaction zone temperature was set to 1050° C.; inlet conditions were set to: NH₃ 15 slm, H₂ 20 slm, TMG 135 sccm; and bottom purge inlet conditions were set to: H₂ 3 slm. As shown in FIGS. 7A (1050° C. plate temperature), 7B (normal plate temperature, radiant heat), and 7C (27° C. plate temperature), there is a significant increase in particulate formation (both along the wafer and at the exit) when isothermal reaction conditions are not created within the reaction zone. Thus, the simulations predict reductions in particle formations in substantially isothermal reaction conditions in hotwall reactors.

### B. Example 2

### Increase in Deposition Rate Under Substantially Isothermal Conditions

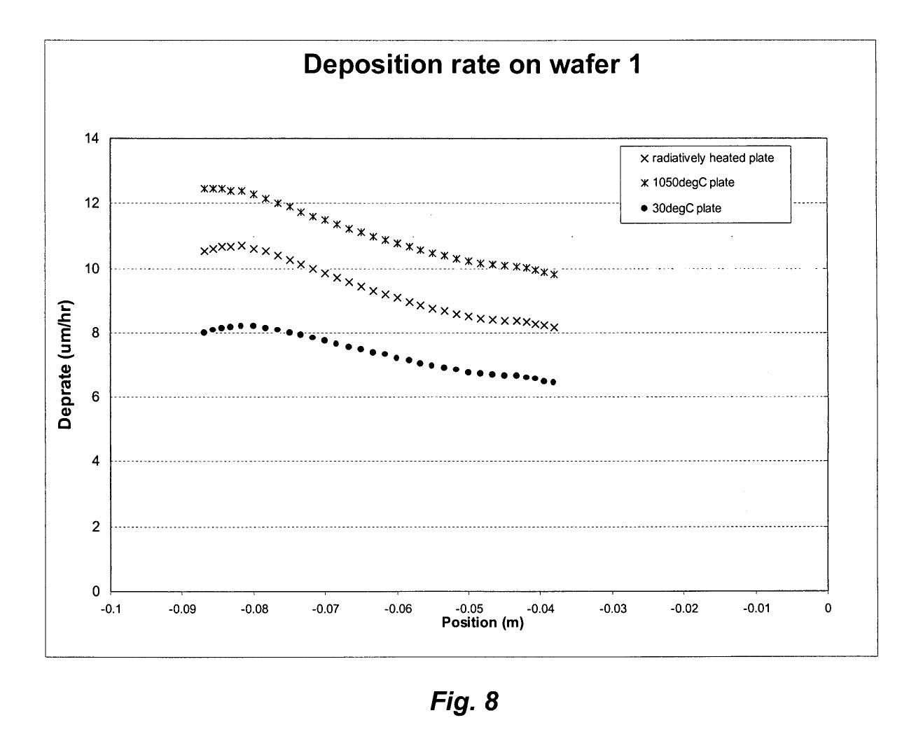

Simulations were also run to investigate the effect of hotwall depositions on deposition rate. Pressure was set to 200 Torr; reaction zone temperature was set to 1050° C.; inlet conditions were set to: NH₃ 15 slm, H₂ 20 slm, TMG 27 sccm, and bottom purge inlet conditions were set to: H₂ 3 slm. As shown in FIG. 8, the top deposition rate was found for the 1050° C. plate (*), ranging from just above 12 μm/hr to just below 10 μm/hr. The radiatively heated plate (x) was found to have a deposition rate just above 10 μm/hr at the near end to just above 8 μm/hr at the far end, while the 30° C. plate (▴) was found to have a deposition rate of just above 8 μm/hr at the near end to just above 6 μm/hr at the far end. As such, the simulations predict improved deposition rates in hotwall reactors for reaction conditions as isothermal conditions are approximated.

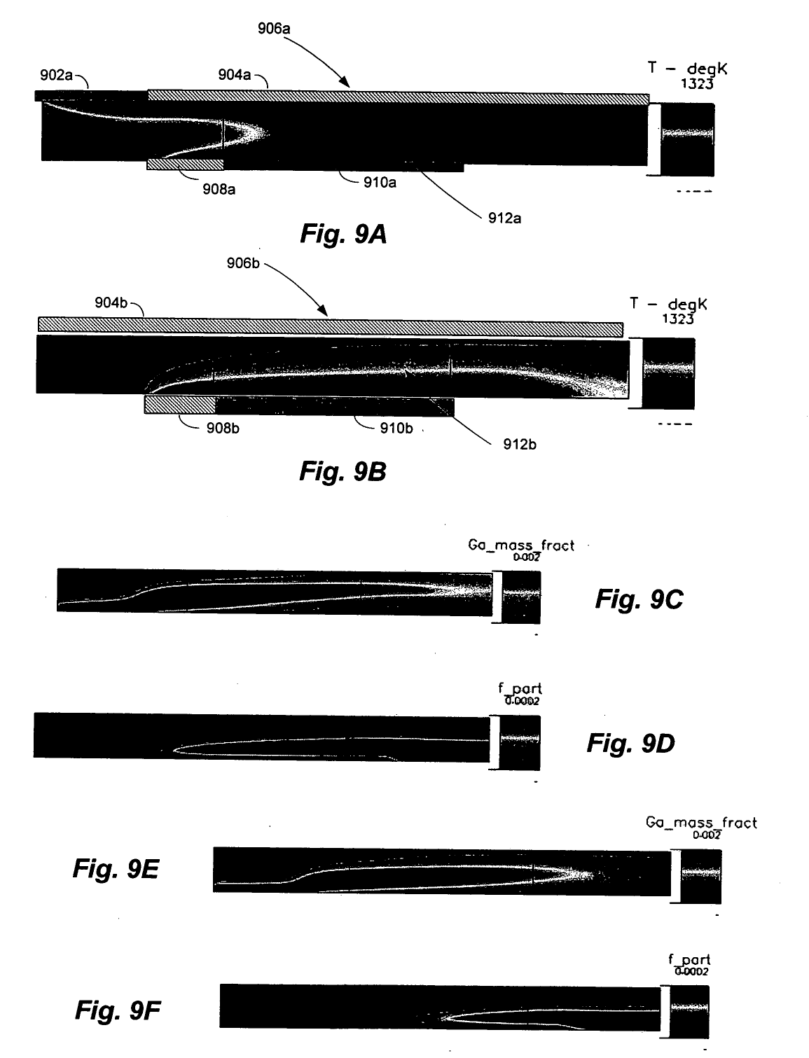

The results of additional simulations are shown in FIG. 9A-9F. FIG. 9A shows a hotwall configuration, wherein a substantially isothermal reaction zone 912a is formed between pre-heat region 902a, having a temperature in the range of 950-1050° C. and hotwall region 904a, having a temperature of 1050° C., of top-plate 906a and the edge ring 908a and wafer 910a, both having a temperature of 1050° C., at the susceptor (not shown). Contrary to this, FIG. 9B shows a substantially non-isothermal reaction zone 912b is formed between cold-wall top-plate 906b and the edge ring 908b and wafer 910b, both having a temperature of 1050° C., at the susceptor (not shown).

FIGS. 9C and 9D illustrate simulated results in a cold-wall reactor environment (i.e., non-isothermal reaction zone), while FIGS. 9E and 9F illustrate simulated results in hotwall reactor environment (i.e., substantially isothermal reaction zone). As shown in FIG. 9C-9F, there is a signification decrease in particulate formation (FIGS. 9E and 9F) in the reaction zone in connection with a corresponding decrease in Ga mass fraction distribution (FIGS. 9C and 9D) in the hotwall reactor as compared to the cold-wall reactor, thereby indicating an improved efficiency of deposition in hotwall reactor conditions (i.e., substantially isothermal reaction conditions). Further simulation results indicate a cold-wall deposition rate of about 3.4 um/hr and a hotwall deposition rate of about 5.3 um/hr for approximately a 55% deposition rate improvement.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of suppressing parasitic particle formation in a metal organic chemical vapor deposition process for deposition of III-V nitride films, the method comprising:
providing a substrate to a reaction chamber including at least a susceptor for supporting the substrate and a top-plate disposed above the substrate;
introducing a Group-III organometallic precursor and at least nitrogen-containing precursor to the reaction chamber, wherein the nitrogen-containing precursor reacts with the Group-III organometallic precursor; and
forming a deposition layer on the substrate from a reaction mixture comprising the Group-III organometallic precursor and the nitrogen-containing precursor under substantially isothermal reaction conditions such that parasitic particle formation is suppressed in the reaction chamber.

2. The particle suppression method of claim 1, wherein the reaction chamber top-plate is heated to a temperature substantially isothermal with the susceptor to thereby provide said substantially isothermal reaction conditions.

3. The particle suppression method of claim 1, wherein said deposition layer is selected from a nucleation layer or an epitaxial layer.

4. The particle suppression method of claim 1, wherein the substrate comprises an aluminum or silicon material.

5. The particle suppression method of claim 4, wherein the aluminum material comprises sapphire.

6. The particle suppression method of claim 4, wherein the silicon material comprises substantially pure silicon or silicon carbide.

7. The particle suppression method of claim 1, wherein the substrate comprises spinel, lithium gallate, or zinc oxide.

8. The particle suppression method of claim 1, wherein the Group-III organometallic precursor comprises an organo-gallium compound.

9. The particle suppression method of claim 8, wherein the organo-gallium compound comprises trimethyl gallium.

10. The particle suppression method of claim 1, wherein the nitrogen-containing precursor comprises ammonia.

11. The particle suppression method of claim 1, wherein the deposition layer comprises gallium nitride, or an alloy of gallium nitride.

12. The particle suppression method of claim 1, wherein the method comprises introducing a third precursor to the reaction chamber that reacts with the Group-III organometallic precursor and the nitrogen-containing precursor to form the deposition layer.

13. The particle suppression method of claim 1, wherein the deposition layer is a nucleation layer, and the method further comprises forming a epitaxial layer on the nucleation layer with a hydride vapor-phase epitaxy process.

14. The particle suppression method of claim 13, wherein the hydride vapor-phase epitaxy process comprises:
introducing a metal containing reagent gas into the reaction chamber, wherein the metal containing reagent gas is generated from the reaction of a metal with a halogen containing gas; and
introducing a second reagent gas into the reaction chamber, wherein the second reagent gas reacts with the metal containing reagent gas; and
forming the epitaxial layer on the nucleation layer from a epitaxial reaction gas mixture comprising the metal containing gas and the second reagent gas under substantially isothermal reaction conditions such that parasitic particle formation is suppressed in the reaction chamber.

15. The particle suppression method of claim 14, wherein the metal reaction with the halogen containing gas is a liquid metal selected from the group consisting of aluminum, gallium, and indium.

16. The particle suppression method of claim 14, wherein the metal containing reagent gas comprises aluminum chloride, gallium chloride, or indium chloride.

17. The particle suppression method of claim 14, wherein the halogen containing gas comprises hydrogen chloride.

18. The particle suppression method of claim 14, wherein the second reagent gas comprises ammonia.

19. The particle suppression method of claim 13, wherein the epitaxial layer comprises aluminum nitride, or indium nitride.

20. The particle suppression method of claim 13, wherein the epitaxial layer comprises gallium nitride, or alloys of gallium nitride.

21. The particle suppression method of claim 13, wherein the nucleation layer has a thickness of about 100 Å to about 1000 Å, and the epitaxial layer has a thickness of about 1 μm or more.

22. A method of suppressing parasitic particle formation during formation of a gallium nitride layer on a sapphire substrate, the method comprising:
introducing ammonia to a reaction chamber that includes the sapphire substrate;
introducing an organo-gallium compound to a reaction chamber under substantially isothermal reaction conditions such that parasitic particle formation is suppressed in the reaction chamber; and
forming a gallium nitride layer on the sapphire substrate.

23. The method of suppressing parasitic particle formation of claim 22, wherein the organo-gallium compound is trimethyl gallium.

24. The method of suppressing parasitic particle formation of claim 22, wherein the reaction chamber includes at least a susceptor for supporting the sapphire substrate and a top-plate disposed above the sapphire substrate; and wherein the reaction chamber top-plate is heated to a temperature substantially isothermal with the susceptor to thereby provide said substantially isothermal reaction conditions.
